(19) United States
(12) Patent Application Publication
(10) Pub. No.: US 2025/0133756 A1
(43) Pub. Date: Apr. 24, 2025

(54) DOPED REGIONS FOR NEUTRALIZING ELECTRONS IN DIODE STRUCTURES

(71) Applicant: Taiwan Semiconductor Manufacturing Company, Ltd., Hsin-Chu (TW)

(72) Inventors: Chen-Ming Lee, Taoyuan County (TW); Zi-Ang Su, Taoyuan County (TW); Ming-Shuan Li, Hsinchu County (TW); I-Wen Wu, Hsinchu City (TW)

(21) Appl. No.: 18/492,295

(22) Filed: Oct. 23, 2023

(51) Int. Cl. H01L 29/868; H01L 29/06; H01L 29/417; H01L 29/423; H01L 29/66; H01L 29/775; H01L 29/786

(52) U.S. Cl. CPC H10D 8/50; H10D 8/01; H10D 30/014; H10D 30/43; H10D 30/6735; H10D 30/6757; H10D 62/121; H10D 64/23

(57) ABSTRACT

A diode is formed in an active region. The diode includes a P-type component embedded in a first portion of the active region, an N-type component embedded in a second portion of the active region, and an undoped component disposed between the P-type component and the N-type component. An interconnect structure is formed over a first side of the diode. Different portions of the interconnect structure are electrically coupled to the P-type component and the N-type component, respectively. One or more openings are etched through a dielectric structure disposed over a second side of the diode opposite the first side. A dopant material is implanted into the active region through the one or more openings. The one or more openings are filled with a conductive material.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

However, as the scaling down process continues, it has brought about certain fabrication challenges. For example, the fabrication of diode structures may cause positively charged particles to be present within a dielectric structure. The presence of the positively charged particles may attract electrons near the dielectric structure, which could lead to worse device performance and is therefore undesirable.

As a result, although certain diode fabrication processes have been generally adequate for their intended purposes, they have not been entirely satisfactory in every aspect.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. It is also emphasized that the drawings appended illustrate only typical embodiments of this invention and are therefore not to be considered limiting in scope, for the invention may apply equally well to other embodiments.

FIG. 1A illustrates a three-dimensional perspective view of a FinFET device.

FIG. 1B illustrates a top view of a FinFET device.

FIG. 1C illustrates a three-dimensional perspective view of a multi-channel gate-all-around (GAA) device.

FIG. 2A is a top view of a diode structure.

FIG. 2B is a cross-sectional view of a diode structure.

FIG. 2C is a three-dimensional perspective view of a diode structure.

FIGS. 3-12 illustrate a series of cross-sectional side views of an IC device at various stages of fabrication according to various aspects of the present disclosure.

FIG. 13 is a block diagram of a manufacturing system according to various aspects of the present disclosure.

FIGS. 14-15 are flowcharts illustrating methods of IC fabrication according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Still further, when a number or a range of numbers is described with “about,” “approximate,” and the like, the term is intended to encompass numbers that are within a reasonable range including the number described, such as within +/−10% of the number described or other values as understood by person skilled in the art. For example, the term “about 5 nm” encompasses the dimension range from 4.5 nm to 5.5 nm.

The present disclosure is generally related to improving the performance of Integrated Circuit (IC) devices that include diode structures. In more detail, diode structures may be formed as a type of a passive IC component. For example, diode structures may be formed by doping a portion of a semiconductor material with a P-type dopant and doping another portion of the semiconductor material with an N-type dopant. In this manner, a P-N junction of a diode may be formed. Diode structures may also include PIN diodes, where the P-type component and the N-type component of the diode structure are separated by an undoped semiconductor component (also referred to as an intrinsic component).

As semiconductor devices continue to get scaled down, three-dimensional transistor devices such as FinFETs or multi-channel gate-all-around (GAA) devices have gained popularity in recent years. To ensure fabrication compatibility with these three-dimensional transistors, fin diodes (compatible with FinFET fabrication) or lateral PIN diodes (compatible with GAA fabrication) may be formed on an IC in which the three-dimensional transistors are formed. However, certain challenges remain in association with the fabrication of these diodes. For example, in a lateral PIN diode fabricated along with GAA transistors, a dielectric structure may be positioned near the lateral PIN diode. The fabrication of the GAA transistors may involve various etching processes, where positively charged plasma may be used. The positively charged plasma may enter the portion of the IC where the lateral PIN diode structure is formed. For example, some of the positively charged particles may enter the dielectric structure that is positioned near the lateral PIN diode. The presence of the positively charged particles in the dielectric structure may attract electrons. Unfortunately, when a sufficiently large number of electrons congregate near a surface of the dielectric structure, it could adversely affect the performance of the lateral PIN diode. For example, these electrons could cause unintended voltage fluctuations, which are undesirable. Diode junction capacitance and/or a reverse current of the diode may also suffer, thereby leading to degradation in device performance.

The present disclosure implements various charge potential equivalence control (CPEC) structures to address the issues discussed above. In some embodiments, the CPEC structure may include extra electrical interconnection structures. These extra electrical interconnection structures—such as vias and metal lines—may be used to prevent the positively charged plasma from entering the IC device, which would in turn prevent the electrons from congregating near the dielectric structure. In this manner, the extra electrical interconnection structures (as an embodiment of the CPEC structure) may eliminate or reduce the potential damage caused by the presence of the plasma. In some other embodiments, the CPEC structure may include one or more extra P-type doped region formed between the PIN diode and the dielectric structure. The P-type doped regions attract electrons that would otherwise be attracted to the surface of the dielectric structure. The electrons attracted to the P-type doped region may compensate against each other (e.g., cancel each other out in terms of electrical charge). In this manner, the problem of excessive electrons congregating near the dielectric structure can also be alleviated, and in turn, device performance may be improved.

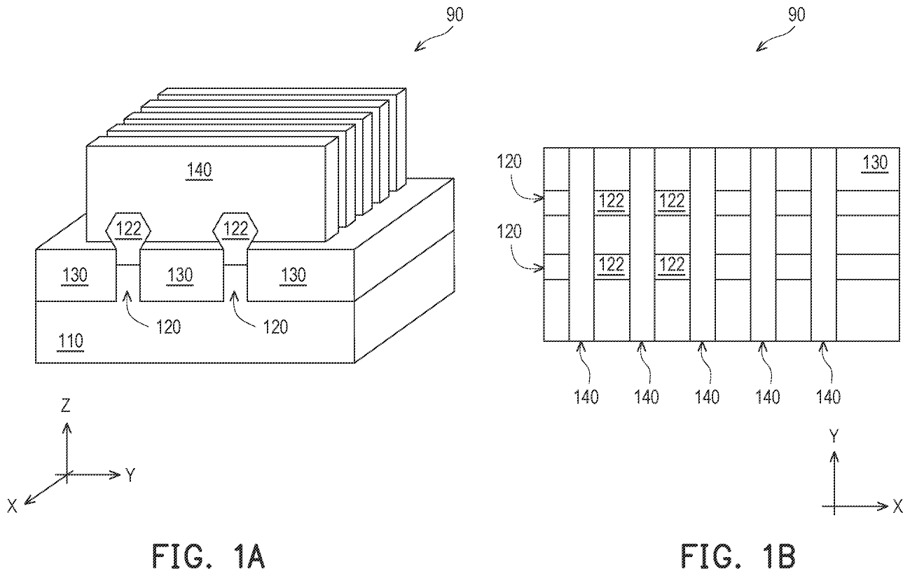

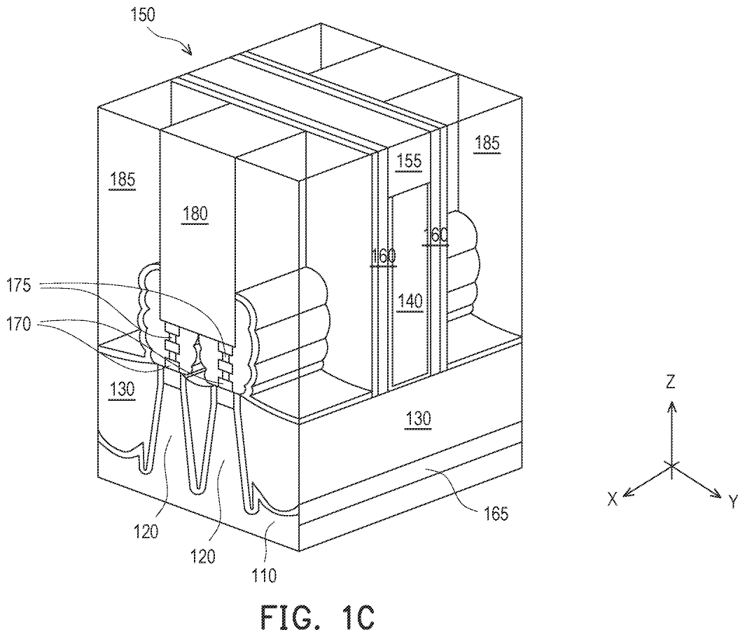

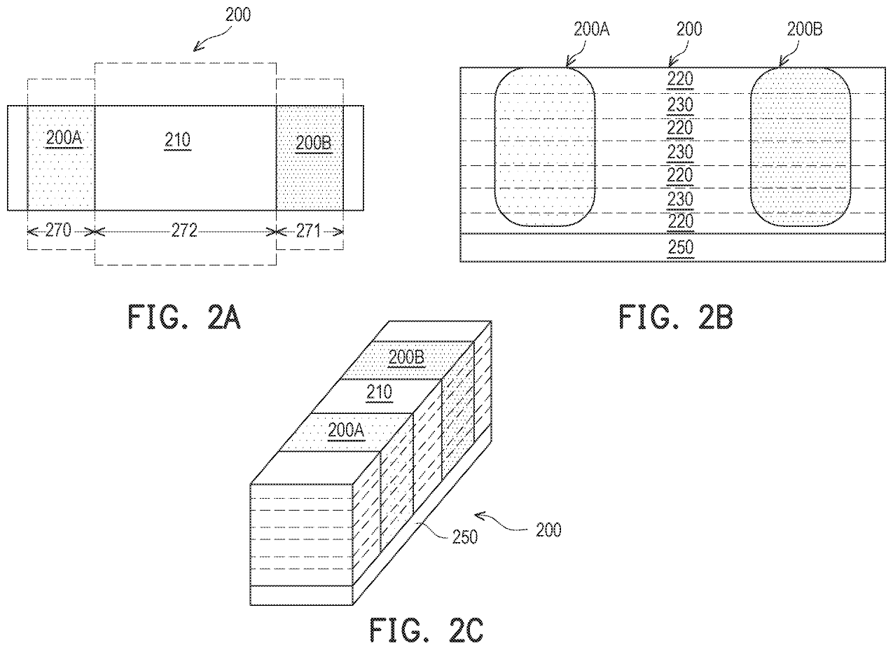

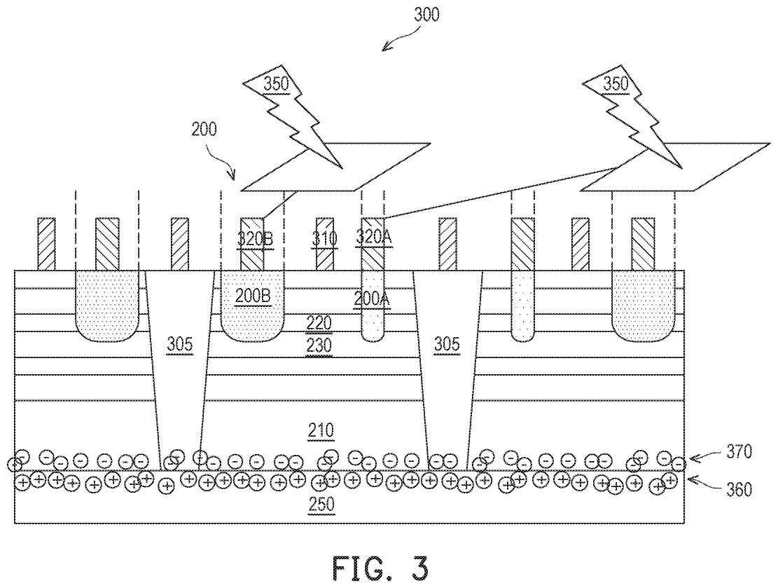

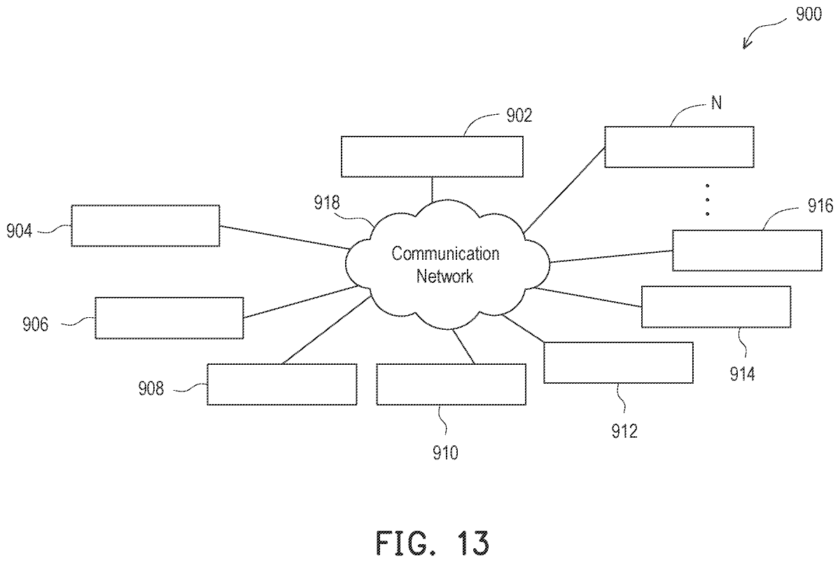

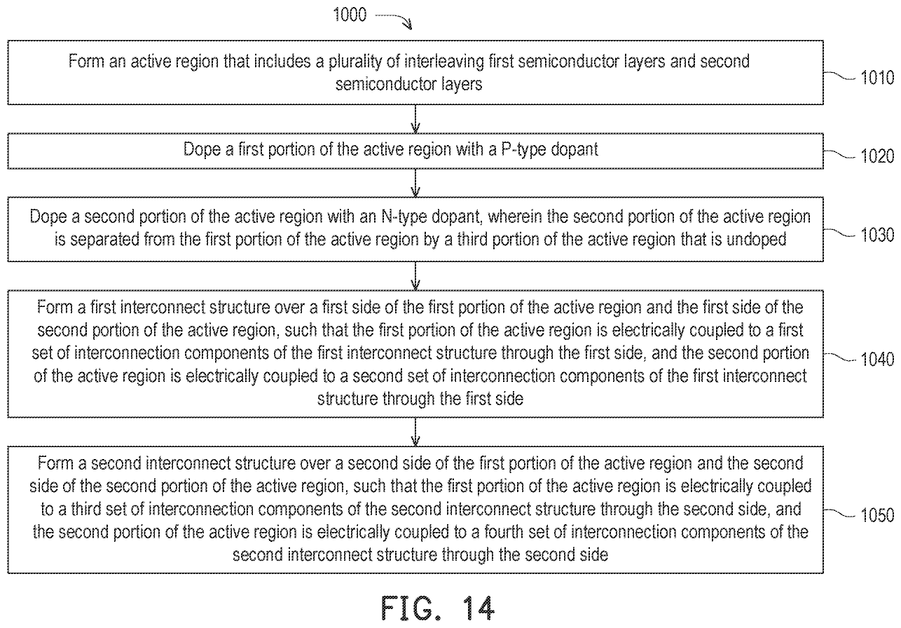

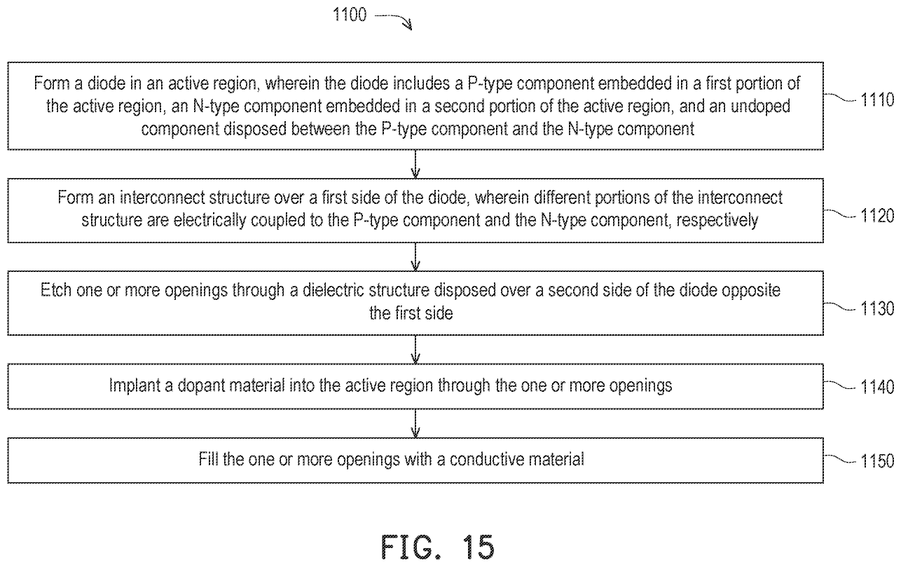

The various aspects of the present disclosure are now discussed in more detail with reference to FIGS. 1A, 1B, 1C, 2A, 2B, 2C, and 3-15. In more detail, FIGS. 1A-B illustrate an example FinFET device, and FIG. 1C illustrates an example GAA device. FIGS. 2A-2C illustrate the top view, the cross-sectional side view, and the three-dimensional perspective view of a diode. FIGS. 3-12 illustrate cross-sectional side views of a portion of an IC device at various stages of fabrication according to embodiments of the present disclosure. FIG. 13 illustrates a semiconductor fabrication system that may be used to fabricate the IC device of the present disclosure. FIGS. 14-15 each illustrates a method of fabricating an IC device according to various aspects of the present disclosure.

Referring now to FIGS. 1A and 1B, a three-dimensional perspective view and a top view of a portion of an Integrated Circuit (IC) device 90 are illustrated, respectively. The IC device 90 is implemented using field-effect transistors (FETs) such as three-dimensional fin-line FETs (FinFETs). FinFET devices have semiconductor fin structures that protrude vertically out of a substrate. The fin structures are active regions, from which source/drain region(s) and/or channel regions are formed. Source/drain region(s) may refer to a source or a drain, individually or collectively dependent upon the context. A source/drain region may also refer to a region that provides a source and/or drain for multiple devices. The gate structures partially wrap around the fin structures. In recent years, FinFET devices have gained popularity due to their enhanced performance compared to conventional planar transistors.

As shown in FIG. 1A, the IC device 90 includes a substrate 110. The substrate 110 may comprise an elementary (single element) semiconductor, such as silicon, germanium, and/or other suitable materials; a compound semiconductor, such as silicon carbide, gallium arsenic, gallium phosphide, indium phosphide, indium arsenide, indium antimonide, and/or other suitable materials; an alloy semiconductor such as SiGe, GaAsP, AlInAs, AlGaAs, GaInAs, GaInP, GaInAsP, and/or other suitable materials. The substrate 110 may be a single-layer material having a uniform composition. Alternatively, the substrate 110 may include multiple material layers having similar or different compositions suitable for IC device manufacturing. In one example, the substrate 110 may be a silicon-on-insulator (SOI) substrate having a semiconductor silicon layer formed on a silicon oxide layer. In another example, the substrate 110 may include a conductive layer, a semiconductor layer, a dielectric layer, other layers, or combinations thereof. Various doped regions, such as source/drain regions, may be formed in or on the substrate 110. The doped regions may be doped with n-type dopants, such as phosphorus or arsenic, and/or p-type dopants, such as boron, depending on design requirements. The doped regions may be formed directly on the substrate 110, in a p-well structure, in an n-well structure, in a dual-well structure, or using a raised structure. Doped regions may be formed by implantation of dopant atoms, in-situ doped epitaxial growth, and/or other suitable techniques.

Three-dimensional active regions 120 are formed on the substrate 110. The active regions 120 may include elongated fin-like structures that protrude upwardly out of the substrate 110. As such, the active regions 120 may be interchangeably referred to as fin structures 120 or fins 120 hereinafter. The fin structures 120 may be fabricated using suitable processes including photolithography and etch processes. The photolithography process may include forming a photoresist layer overlying the substrate 110, exposing the photoresist to a pattern, performing post-exposure bake processes, and developing the photoresist to form a masking element (not shown) including the resist. The masking element is then used for etching recesses into the substrate 110, leaving the fin structures 120 on the substrate 110. The etching process may include dry etching, wet etching, reactive ion etching (RIE), and/or other suitable processes. In some embodiments, the fin structure 120 may be formed by double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. As an example, a layer may be formed over a substrate and patterned using a photolithography process. Spacers are formed alongside the patterned layer using a self-aligned process. The layer is then removed, and the remaining spacers, or mandrels, may then be used to pattern the fin structures 120.

The IC device 90 also includes source/drain components 122 formed over the fin structures 120. The source/drain components 122 (also referred to source/drain regions) may refer to a source or a drain of a transistor, individually or collectively, dependent upon the context. The source/drain components 122 may include epi-layers that are epitaxially grown on the fin structures 120. The IC device 90 further includes isolation structures 130 formed over the substrate 110. The isolation structures 130 electrically separate various components of the IC device 90. The isolation structures 130 may include silicon oxide, silicon nitride, silicon oxynitride, fluoride-doped silicate glass (FSG), a low-k dielectric material, and/or other suitable materials. In some embodiments, the isolation structures 130 may include shallow trench isolation (STI) features. In one embodiment, the isolation structures 130 are formed by etching trenches in the substrate 110 during the formation of the fin structures 120. The trenches may then be filled with an isolating material described above, followed by a chemical mechanical planarization (CMP) process. Other isolation structure such as field oxide, local oxidation of silicon (LOCOS), and/or other suitable structures may also be implemented as the isolation structures 130. Alternatively, the isolation structures 130 may include a multi-layer structure, for example, having one or more thermal oxide liner layers.

The IC device 90 also includes gate structures 140 formed over and engaging the fin structures 120 on three sides in a channel region of each fin 120. In other words, the gate structures 140 each wrap around a plurality of fin structures 120. The gate structures 140 may be dummy gate structures (e.g., containing an oxide gate dielectric and a polysilicon gate electrode), or they may be High-k metal gate (HKMG) structures that contain a high-k gate dielectric and a metal gate electrode, where the HKMG structures are formed by replacing the dummy gate structures. Though not depicted herein, the gate structure 140 may include additional material layers, such as an interfacial layer over the fin structures 120, a capping layer, other suitable layers, or combinations thereof.

Referring to FIGS. 1A-1B, multiple fin structures 120 are each oriented lengthwise along the X-direction, and multiple gate structures 140 are each oriented lengthwise along the Y-direction, i.e., generally perpendicular to the fin structures 120. In many embodiments, the IC device 90 includes additional features such as gate spacers disposed along sidewalls of the gate structures 140, hard mask layer(s) disposed over the gate structures 140, and numerous other features.

FIG. 1C illustrates a three-dimensional perspective view of an example multi-channel gate-all-around (GAA) device 150. GAA devices have multiple elongated nano-structure channels that may be implemented as nano-tubes, nano-sheets, or nano-wires. For reasons of consistency and clarity, similar components in FIG. 1C and FIGS. 1A-1B will be labeled the same. For example, active regions such as fin structures 120 rise vertically upwards out of the substrate 110 in the Z-direction. The isolation structures 130 provide electrical separation between the fin structures 120. The gate structure 140 is located over the fin structures 120 and over the isolation structures 130. A layer 155 is located over the gate structure 140, and gate spacer structures 160 are located on sidewalls of the gate structure 140. A capping layer 165 is formed over the fin structures 120 to protect the fin structures 120 from oxidation during the forming of the isolation structures 130.

A plurality of nano-structures 170 is disposed over each of the fin structures 120. The nano-structures 170 may include nano-sheets, nano-tubes, or nano-wires, or some other type of nano-structure that extends horizontally in the X-direction. Portions of the nano-structures 170 under the gate structure 140 may serve as the channels of the GAA device 150. Dielectric inner spacers 175 may be disposed between the nano-structures 170. In addition, although not illustrated for reasons of simplicity, each stack of the nano-structures 170 may be wrapped around circumferentially by a gate dielectric as well as a gate electrode. In the illustrated embodiment, the portions of the nano-structures 170 outside the gate structure 140 may serve as the source/drain features of the GAA device 150. However, in some embodiments, continuous source/drain features may be epitaxially grown over portions of the fin structures 120 outside of the gate structure 140. Regardless, conductive source/drain contacts 180 may be formed over the source/drain features to provide electrical connectivity thereto. An interlayer dielectric (ILD) 185 is formed over the isolation structures 130 and around the gate structure 140 and the source/drain contacts 180. The ILD 185 may be referred to as an ILD0 layer. In some embodiments, the ILD 185 may include silicon oxide, silicon nitride, or a low-k dielectric material.

The FinFET devices of FIGS. 1A-1B and the GAA devices of FIG. 1C may be utilized to implement electrical circuitries having various functionalities, such as memory devices (e.g., static random access memory (SRAM) devices), logic circuitries, input/output (I/O) devices, application specific integrated circuit (ASIC) devices, radio frequency (RF) circuitries, drivers, micro-controllers, central processing units (CPUs), image sensors, etc., as non-limiting examples. Meanwhile, the fabrication process flow for fabricating the FinFET devices or the GAA devices may also be utilized to form certain types of passive devices, such as diodes. The diodes may be formed on the same wafer as the FinFET devices or GAA devices. As discussed above, during the fabrication of the diodes, positively charged plasma could enter the wafer, which could cause damage and/or degrade device performance. According to the various aspects of the present disclosure, a charging potential equivalence control (CPEC) structure may be implemented to alleviate the potential problems caused by the positively charged plasma entering the wafer, as discussed in detail below.

FIGS. 2A, 2B, 2C illustrate a planar top view, a cross-sectional side view, and a three-dimensional perspective view of a PIN diode 200 as an example diode formed according to the various aspects of the present disclosure. The PIN diode 200 includes an active region 210 (also referred to as an OD), which may be formed as the fin structures (in the case of FinFET devices) or as the stack of alternating semiconductor layers (in the case of GAA devices). As a non-limiting example, the active region 210 herein is formed using processes that form the GAA devices, such as the GAA device 150 discussed above with reference to FIG. 1C. As such, the active region 210 includes a stack of interleaving semiconductor layers 220 and 230. The semiconductor layers 220 and 230 have different material compositions. For example, the semiconductor layer 220 may include silicon, while the semiconductor layer 230 may include silicon germanium, or vice versa. It is understood that the active region 210 herein is formed at the same time that the active regions of the GAA devices are formed (i.e., using the same fabrication processes that form the GAA devices).

As discussed above, the active region 210 formed of these interleaving semiconductor layers 220 and 230 may be used to define the channel regions and/or the source/drain regions of the GAA transistors. However, in the case of the PIN diode 200, the active region 210 provides the regions where the P-type component, the N-type component, and the intrinsic component of the PIN diode 200 can be formed. In more detail, an implantation process may be performed to implant a P-type dopant (e.g., boron) into one portion of the active region 210, thereby forming a P-type component 200A. Another implantation process may be performed to implant an N-type dopant (e.g., arsenic or phosphorous) into another portion of the active region 210, thereby forming an N-type component 200B. The P-type component 200A and the N-type component 200B of the PIN diode 200 are separated by an undoped portion of the active region 210, which may also be referred to as the intrinsic portion of the PIN diode 200.

As shown in FIG. 2A, the P-type component 200A, the N-type component 200B, and the intrinsic portion (e.g., the portion of the undoped active region 210 between the P-type component 200A and the N-type component 200B) have different lateral dimensions 270, 271, and 272, respectively. In some embodiments, the lateral dimension 271 is greater than the lateral dimension 272, which is greater than the lateral dimension 270. For example, a ratio between the lateral dimension 270 and the lateral dimension 271 may be in a range between about 1:3 and about 1:3.4, and a ratio between the lateral dimension 270 and the lateral dimension 272 may be in a range between about 1:2.6 and about 1:3. These ratios may be specified by design rules to comply with the fabrication of the GAA devices.

As shown in FIGS. 2B and 2C, a dielectric structure 250 is disposed below the PIN diode 200. In some embodiments, the dielectric structure 250 includes a silicon nitride layer. In some embodiments, the dielectric structure 250 includes multiple dielectric layers, for example, a silicon nitride layer and a silicon oxide layer. As discussed above and will be discussed in further detail below, positively charged plasma may enter the dielectric structure 250, which would then attract electrons around an interface between the dielectric structure 250 and the PIN diode 200. These electrons may affect voltage potentials, increase parasitic capacitance, and/or degrade other diode performance parameters. As such, the present disclosure implements CPEC structures to eliminate or at least reduce the presence of these electrons, which in turn improves device performance.

FIG. 3 is a cross-sectional side view of a portion of an IC device 300 that includes the PIN diode 200. FIG. 3 helps illustrate the issues associated with the positively charged plasma discussed above. In more detail, the PIN diode 200 includes the P-type component 200A, the N-type component 200B, and an undoped portion of the active region 210. The P-type component 200A and the N-type component 200B each extend vertically through a plurality of the interleaving pairs of the semiconductor layers 220 and 230. Note that a plurality of isolation structures 305 are also formed in the portion of the IC device 300 shown in FIG. 3. In some embodiments, the isolation structures 305 include shallow trench isolation (STI) structures. The PIN diode 200 is formed between the isolation structures 305.

Since the fabrication of the PIN diode 200 herein is done using the same fabrication process flow that is used to fabricate the GAA devices (e.g., transistors similar to the GAA transistors 150 of FIG. 1C, but that are formed in another portion of the IC 300), the other components associated with the GAA fabrication may also be formed in the region of the IC 300 that contains the PIN diode 200. For example, a gate structure 310 may be formed over the intrinsic portion of the PIN diode 200 (e.g., over the portion of the active region 210 between the P-type component 200A and the N-type component 200B). Also, a conductive contact 320A and a conductive contact 320B may be formed over the P-type component 200A and over the N-type component 200B of the PIN diode 200, respectively. The counterparts of the conductive contacts 320A and 320B in the GAA portion of the IC device 300 may serve as source/drain contacts. However, the conductive contacts 320A and 320B may function as conduits that allow electrical charges to enter into the IC device 300.

In more detail, during the fabrication of the GAA devices, a plurality of etching processes may be performed. Some of the etching processes may involve the application of positively charged plasma, which is represented in FIG. 3 by reference numerals 350. Since the conductive contacts 320A and 320B are electrically conductive, they may provide an easy electrical path for the positively charged plasma 350 to enter the IC device 300. For example, the positively charged plasma 350 may enter the dielectric structure 250 through the conductive contacts 320A and 320B, and/or through other conductive components. As a result, the dielectric structure 250 may become positively charged. In FIG. 3, this is represented by a plurality of positively charged particles 360 in the dielectric structure 250. The presence of the positively charged particles 360 in the dielectric structure 250 may attract electrons 370 at or near an interface between the dielectric structure 250 and the active region 210 (e.g., a portion of a silicon substrate). The presence of the electrons 370 could lead to unintended voltage fluctuations, and/or degradations in diode junction capacitance or a reverse current of the PIN diode 200, which may be undesirable.

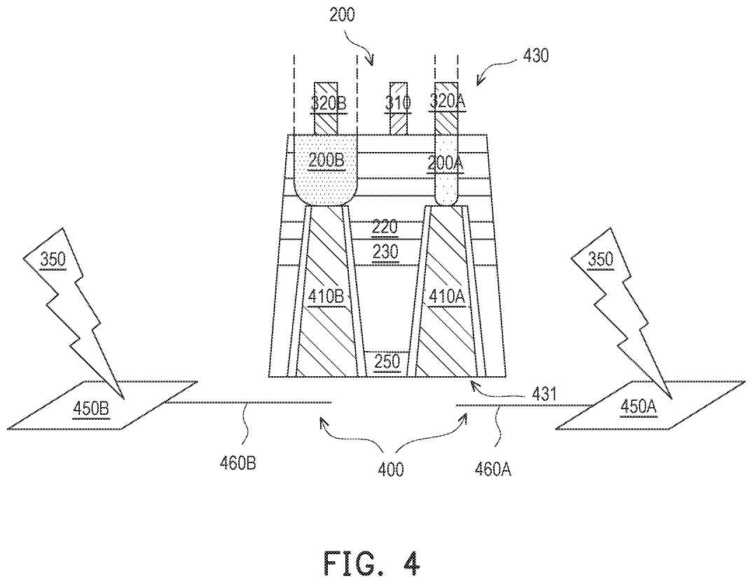

FIG. 4 illustrates a conceptual block diagram of a CPEC structure 400 according to a first embodiment of the present disclosure for alleviating the problems associated with the positively charged plasma 350. In more detail, the CPEC structure 400 includes a conductive via 410A and a conductive via 410B that are electrically coupled to the P-type component 200A and the N-type component 200B of the PIN diode 200, respectively. Whereas the conductive contacts 320A and 320B are formed over a side 430 of the PIN diode 200, the conductive vias 410A and 410B are formed on a side 431 of the PIN diode 200 opposite the side 430. The conductive contact 320A and the conductive via 410A are electrically coupled together through a set of electrical interconnection structures (e.g., vias and metal lines) 460A, such that a first electrical voltage can be applied to both the conductive contact 320A and the conductive via 410A through a conductive pad 450A. In this manner, both sides (e.g., the side 430 and the side 431) of the P-type component 200A of the PIN diode 200 are forced to the same voltage potential, which prevents the positively charged plasma 350 from entering the IC device 300 through the P-type component 200A.

Likewise, the conductive contact 320B and the conductive via 410B are electrically coupled together through a set of electrical interconnection structures (e.g., vias and metal lines) 460B, such that a second electrical voltage can be applied to both the conductive contact 320B and the conductive via 410B through a conductive pad 450B. Again, both sides (e.g., the side 430 and the side 431) of the N-type component 200B of the PIN diode 200 are forced to the same voltage potential, which prevents the positively charged plasma 350 from entering the IC device 300 through the N-type component 200B.

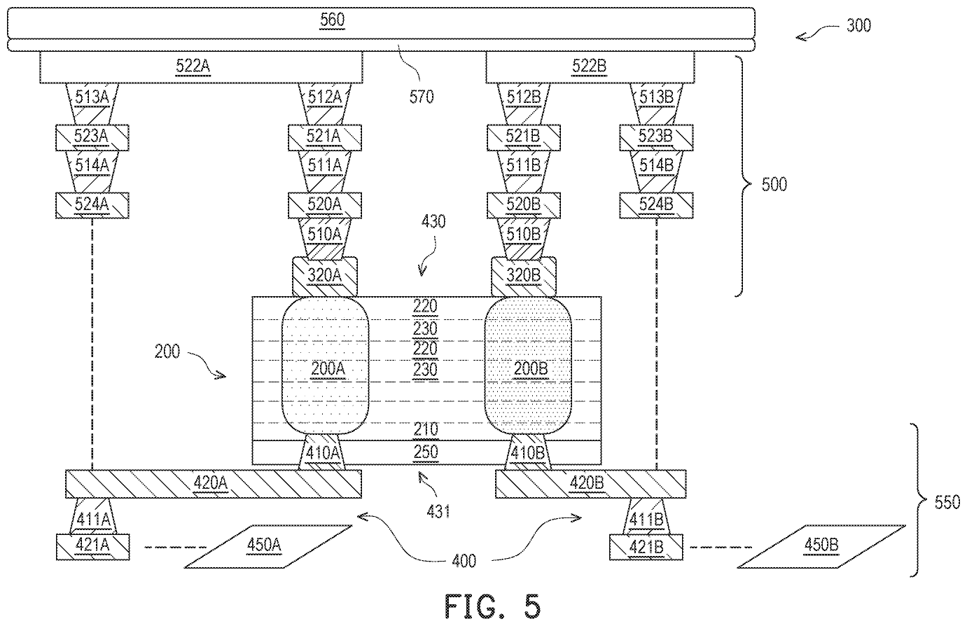

FIG. 5 illustrates a cross-sectional side view of a portion of an IC 300 where the CPEC structure 400 of FIG. 4 is implemented. In more detail, an interconnect structure 500 is formed over the side 430 of the PIN diode 200. The interconnect structure 500 includes a plurality of metal layers containing metal lines, and the metal layers are interconnected together by a plurality of conductive vias. For example, the interconnect structure 500 includes conductive vias 510A-514A and 510B-514B, as well as metal lines 520A-524A and 520B-524B. It is understood that the conductive vias and the metal lines of the interconnect structure 500 illustrated in FIG. 5 are merely to provide a simplified example and are not meant to be limiting unless otherwise claimed.

A subset of the interconnect structure 500 provides electrical connectivity for the P-type component 200A of the PIN diode 200, and another subset of the interconnect structure 500 provides electrical connectivity for the N-type component 200B of the PIN diode 200. For example, the conductive vias 510A-514A and the metal lines 520A-524A are electrically coupled to the P-type component 200A of the PIN diode 200 through the conductive contact 320A. Similarly, the conductive vias 510B-514B and the metal lines 520B-524B are electrically coupled to the N-type component 200B of the PIN diode 200 through the conductive contact 320B.

Meanwhile, an interconnect structure 550 is formed over the side 431 of the PIN diode 200. The interconnect structure 500 may also include a plurality of metal layers containing metal lines and conductive vias. For example, the interconnect structure 550 includes conductive vias 410A-411A and 410B-411B that each extend vertically through the dielectric structure 250. The interconnect structure 550 also includes metal lines 420A-421A and 420B-421B, as well as the conductive pads 450A and 450B discussed above in association with FIG. 4. The metal lines 420A-421A and the conductive via 411A may be viewed as an embodiment of the set of electrical interconnection structures 460A of FIG. 4, and the metal lines 420B-421B and the conductive via 411B may be viewed as an embodiment of the set of electrical interconnection structures 460B of FIG. 4. Again, it is understood that the conductive vias and the metal lines of the interconnect structure 550 illustrated in FIG. 5 are merely to provide a simplified example and are not meant to be limiting unless otherwise claimed.

As discussed above in association with FIG. 4, the conductive via 410A provides electrical connectivity to the P-type component 200A of the PIN diode 200. Since the conductive pad 450A is electrically coupled to the conductive via 410A through the metal lines 420A-421A and the conductive via 411A, an electrical voltage could be applied to the P-type component 200A through the conductive pad 450A when the IC device 300 is in operation. Similarly, the conductive via 410B provides electrical connectivity to the N-type component 200B of the PIN diode 200 when the IC device 300 is in operation. Since the conductive pad 450B is electrically coupled to the conductive via 410B through the metal lines 420B-421B and the conductive via 411B, an electrical voltage could be applied to the N-type component 200B through the conductive pad 450B.

According to various aspects of the present disclosure, the interconnect structure 500 and the interconnect structure 550 are electrically coupled together, such that a same first electrical voltage can be applied to both the side 430 and the side 431 of the P-type component 200A, and a same second electrical voltage can be applied to both the side 430 and the side 431 of the N-type component 200B. For example, the metal line 420A of the interconnect structure 550 is electrically coupled to the portion of the interconnect structure 500 that includes the vias 510A-514A and the metal lines 520A-524A. In other words, a plurality of metal lines and conductive vias may exist between the metal line 420A and the metal line 524A, though they are not specifically illustrated herein for reasons of simplicity. The metal line 420A is also electrically coupled to the conductive via 410A, which is electrically coupled to the P-type component 200A from the side 431. As such, when a first electrical voltage is applied to the conductive pad 450A, the same first electrical voltage will be felt at the metal line 420A, as well as the conductive via 410A and the conductive contact 320A (through the electrical coupling to the conductive vias 510A-514A and the metal lines 520A-524A).

In a similar manner, when a second electrical voltage is applied to the conductive pad 450B, the same second electrical voltage will be felt at the metal line 420B, as well as the conductive via 410B and the conductive contact 320B (through the electrical coupling to the conductive vias 510B-514B and the metal lines 520B-524B). Stated differently, the first electrical voltage may have two paths to reach the P-type component 200A through the side 430 and through the side 431, and the second electrical voltage may have two paths to reach the N-type component 200B through the side 430 and through the side 431, but the voltage potentials are the same for either of those paths. As such, it is difficult for the positively charged plasma to enter the IC device 300, because the substantially identical voltage potentials for both of the electrical paths would effectively prevent a charged particle from entry. In this manner, it may be said that the CPEC structure 400—which includes portions of both of the interconnect structures 500 and 550—can block the positively charged plasma from entering the IC device 300, which in turn would reduce damages caused by the positively charged plasma and improve device performance.

It is understood that the portion of the IC device 300 shown in FIG. 5 is at an intermediate stage of fabrication. For example, the interconnect structure 500 of the IC device 300 is bonded to a carrier wafer 560 through a bonding layer 570 at this stage. Subsequent fabrication processing may remove the IC device 300 from the carrier wafer 560 (and the bonding layer 570).

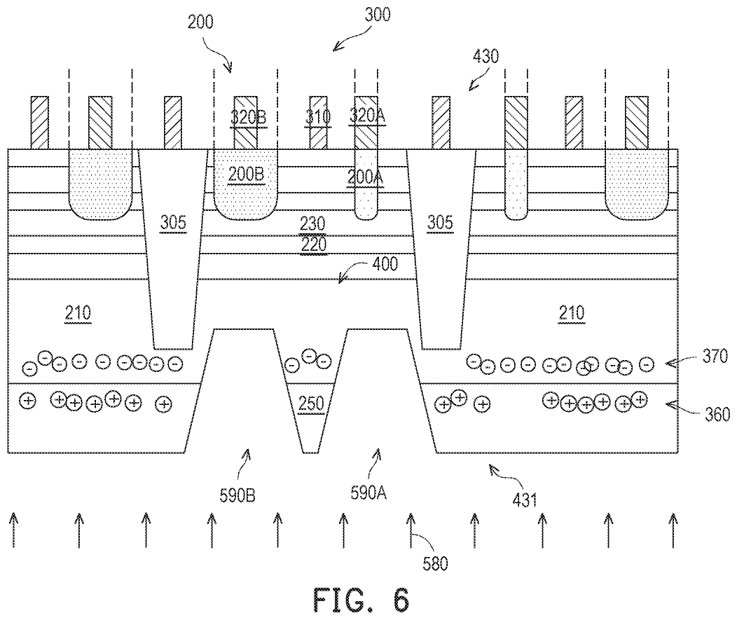

FIGS. 4-5 illustrate a first embodiment of the CPEC structure 400 according to the various aspects of the present disclosure. FIGS. 6-9 illustrate a second embodiment of the CPEC structure 400 according to the various aspects of the present disclosure. According to the second embodiment, the CPEC structure 400 does not utilize extra interconnection components to balance the voltage potential at the side 430 and the side 431 of the PIN diode 200. Instead, the CPEC structure 400 in the second embodiment of FIGS. 6-9 includes one or more doped regions formed in a substrate (e.g., a silicon substrate) of the active region 210. The formation of the one or more doped regions will now be discussed below with reference to FIGS. 6-9. Again, for reasons of clarity and consistency, similar components appearing in FIGS. 4-5 will be labeled the same in FIGS. 6-9.

In more detail, FIGS. 6-8 are cross-sectional side views of a portion of the IC device 300 at various stages of fabrication according to the second embodiment of the present disclosure. Referring now to FIG. 6, one or more etching processes 580 are performed to the IC device 300 from the side 431. The one or more etching processes 580 may include dry etching processes in some embodiments, or wet etching processes in some other embodiments. It is understood that the one or more etching processes 580 may also be performed simultaneously to another portion of the IC device 300 that contains the GAA transistors, so that via trench openings are formed to establish electrical connectivity for the GAA transistors from the side 431. For the portion of the IC device 300 shown in FIG. 6, the etching processes 580 etch one or more trench openings, such as trench opening 590A and 590B. The via trench openings 590A and 590B each extend vertically through the dielectric structure 250, as well as a portion of the active region 210. However, the via trench openings 590A and 590B are not etched deep enough to expose the P-type component 200A or the N-type component 200B of the PIN diode 200 to the side 431. Note that the positively charged particles 360 may already be present in the dielectric structure 250 at this stage of fabrication, which could then attract the electrons 370 to congregate near an interface between the dielectric structure 250 and the active region 210.

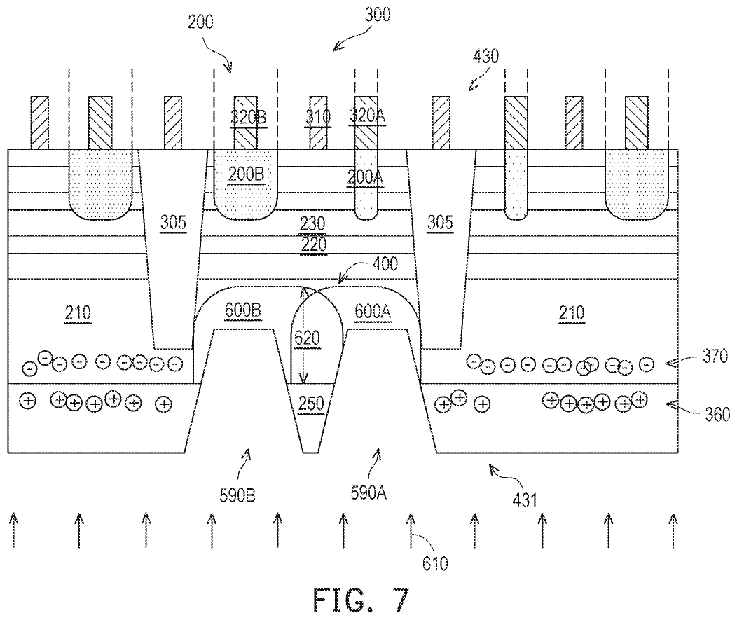

Referring now to FIG. 7, a dopant implantation process 610 is performed to implant a dopant material into the active region 210 through the via trench openings 590A and 590B from the side 431. In some embodiments, the dopant implantation process 610 implants a P-type dopant material (e.g., boron) into the active region 210. The implanted dopant materials form one or more doped regions in the active region, depending on the number (and/or size) of the via trench openings through which the dopant material is implanted. In the embodiment illustrated in FIG. 7, doped regions 600A and 600B (e.g., P-type doped regions containing boron) are formed in the active region 210 as a part of the CPEC structure 400. Since the dopant implantation process 610 is performed from the side 431, the doped regions 600A and 600B each extend from the side 431 toward the side 410. The doped regions 600A and 600B may laterally merge into one another in the embodiment of FIG. 7, but it is understood that they may be spaced apart from one another in other embodiments.

The doped regions 600A and 600B are disposed over the conductive vias 410A and 410B, respectively. This is because the via trench openings 590A and 590B are aligned with the conductive vias 410A and 410B, respectively. According to the various aspects of the present disclosure, since the doped regions 600A and 600B contain P-type dopants, they will attract and neutralize at least a subset of the electrons 370 that would otherwise be attracted to the interface between the dielectric structure 250 and the substrate of the active region 210. In this manner, the presence of the doped regions 600A and 600B will reduce the number of electrons 370 that congregate near the dielectric structure 250, even if the dielectric structure 250 still contains the positively charged particles 360. In this manner, potential damages to the IC device 300 may be reduced, and/or the performance of the IC device 300 may be improved.

It is understood that the locations and/or sizes of the doped regions 600A and 600B may be flexibly configured by tuning various fabrication process parameters of the present disclosure. For example, the location of each of the doped regions 600A and 600B is largely dependent on the location of the via trench opening 590A and 590B through which the dopant material is implanted. In other words, the doped region 600A may be generally aligned with the via trench opening 590A vertically, and the doped region 600B may be generally aligned with the via trench opening 590B vertically.

The width (lateral dimension) of the doped regions 600A and 600B is also correlated with the width of the via trench openings 590A and 590B, respectively. As such, adjusting the width of the via trench opening 590A and 590B may affect the width of the doped regions 600A and 600B too. However, it is understood that the width of the via trench opening 590A and 590B is typically set according to the design and/or fabrication specifications for the transistors (e.g., GAA transistors) in a different portion of the IC device 300. In other words, the fabrication processes performed to etch (and subsequently fill) the via trench openings 590A and 590B are the same processes used to form the conductive vias for the GAA devices that are on the same wafer (e.g., as a different portion of the IC device 300). Since the GAA fabrication may be the primary concern, the sizes of the via trench openings 590A and 590B may also be mostly inherited from the GAA transistor fabrication.

Nevertheless, the number of the via trench openings 590A and 590B may still be configured to effectively adjust the width of the overall doped regions 600A-600B, since the doped regions 600A-600B may merge into one another when a sufficient number of trench openings are formed, and the doped regions 600A-600B may be viewed as a single doped region when the merging occurs. In the embodiment of FIG. 7, the merged doped regions 600A-600B may span laterally from one of the isolation structures 305 to a neighboring isolation structure 305. As such, the doped regions 600A-600B collectively may be wider than the P-type doped component 200A and/or the N-type doped component 200B of the PIN diode 200. The wider width of the doped regions 600A-600B may be more beneficial in terms of attracting and neutralizing the electrons 370. However, the size of the doped regions 600A-600B is not too big to interfere with the proper operation of the PIN diode 200.

A depth 620 (e.g., vertical dimension) of the doped regions 600A and 600B may also be configured by adjusting the parameters of the dopant implant process. For example, by changing the implantation energy, the depth of the doped regions 600A and 600B may be changed. A depth of the trench openings—which may also be dictated by the corresponding GAA processes—may also affect the depth of the doped regions 600A and 600B. In the embodiment of FIG. 7, the depth 620 of the doped regions 600A and 600B extends into the substrate of the active region 210, but does not reach the P-type doped component 200A or the N-type doped component 200B of the PIN diode 200. This helps to ensure that the doped regions 600A and 600B will not adversely interfere with the proper operation of the PIN diode 200.

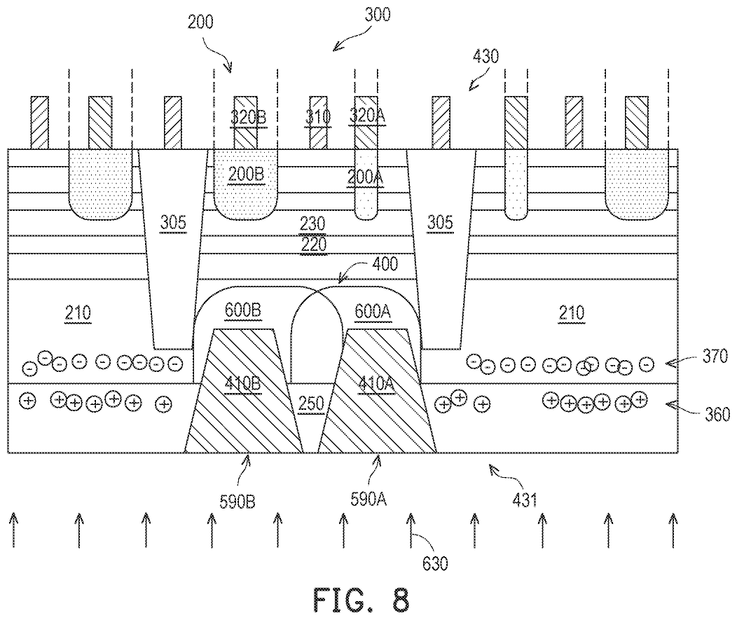

Referring now to FIG. 8, a deposition process 630 is performed to the IC device 300 from the side 431 to fill the via trench openings 590A and 590B with one or more conductive materials. In some embodiments, the deposition process 630 may include a chemical vapor deposition (CVD) process, a physical vapor deposition (PVD) process, an atomic layer deposition (ALD) process, or combinations thereof. A planarization process, such as a chemical mechanical polishing (CMP) process, may also be performed to planarize the surfaces of the deposited conductive materials in the via trench openings 590A and 590B with the surface of the dielectric structure 250 facing the side 431. As a result, conductive vias 410A and 410B are formed in the via trench openings 590A and 590B. As discussed above, conductive vias similar to the conductive vias 410A and 410B are formed in the region of the IC device 300 containing the GAA devices as well. Thus, it can be seen that the present disclosure leverages the fabrication processes for the GAA region of the IC device 300 to achieve additional objectives customized for the non-GAA region of the IC device 300 (e.g., the PIN diode 200 region), which saves on fabrication costs and processing time.

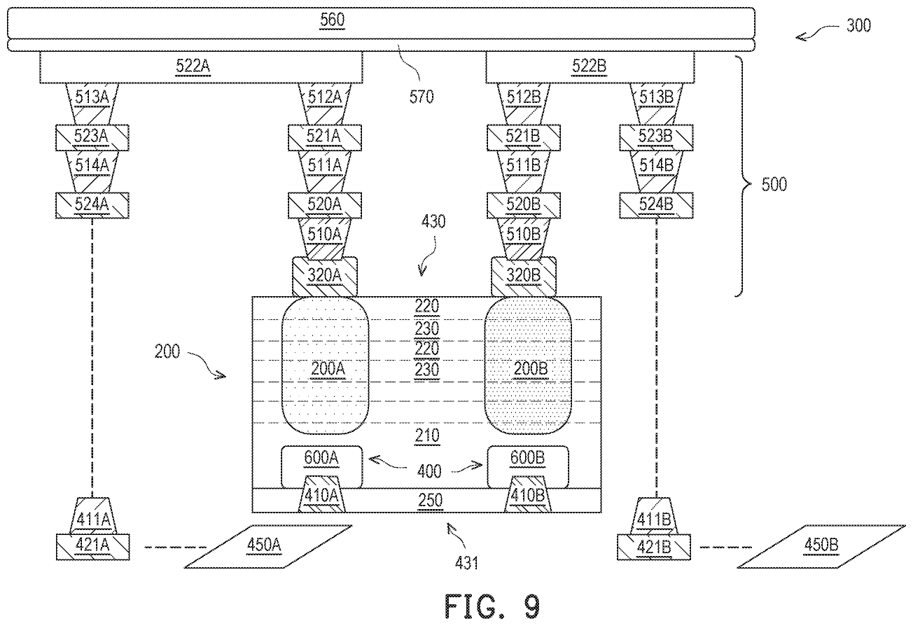

FIG. 9 illustrates a cross-sectional side view of a portion of an IC 300 where the CPEC structure 400 of FIG. 8 is implemented. For example, the CPEC structure 400 shown in FIG. 9 also includes doped regions 600A and 600B that are doped with a P-type dopant. Unlike the CPEC structure 400 in FIG. 8, however, the CPEC structure 400 in FIG. 9 is configured such that the doped regions 600A and 600B do not merge into one another, but are instead spaced apart by a portion of the active region 210. The doped regions 600A and 600B, along with their corresponding conductive vias 410A and 410B, are vertically aligned with the P-type component 200A and the N-type component 200B of the PIN diode 200, respectively.

As discussed above, the doped regions 600A and 600B help attract and neutralize the electrons that would otherwise be congregated near the upper surface of the dielectric structure 250 due to the issues caused by the positively charged plasma. As such, although the IC device 300 herein does not use the extra interconnection components (e.g., the metal lines 420A and 420B of FIG. 5) of the first embodiment of the CPEC structure 400 to balance the voltage potentials for the PIN diode 200, the harmful effects caused by the positively charged plasma can still be substantially mitigated. It is understood that the positively charged particles 360 and the electrons 370 are not specifically illustrated in FIG. 9 for reasons of simplicity.

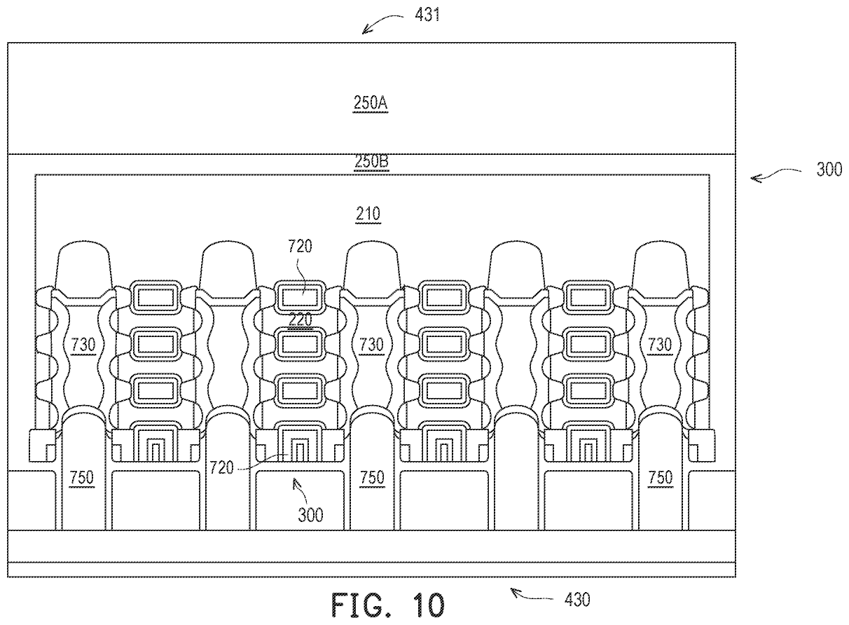

To provide additional context of the second embodiment of the present disclosure, FIGS. 10-12 illustrate the cross-sectional side views of the GAA portion of the IC device 300 undergoing a series of fabrication processes that correspond to the formation of the conductive vias 410A and 410B discussed above. Again, for reasons of clarity and consistency, similar components appearing in FIGS. 4-9 will be labeled the same in FIGS. 10-12. It is also noted that the sides 430 and 431 in FIGS. 10-12 are vertically flipped from the sides 430 and 431 in FIGS. 4-9.

Referring now to FIG. 10, the GAA portion of the IC device 300 includes a plurality of GAA transistors 700 as embodiments of the GAA transistor 150 discussed above with reference to FIG. 1C. Each of the GAA transistors 700 may be formed at least in part using the active region 210 discussed above. For example, each of the GAA transistors 700 may include a stack of nano-structure channels (e.g., nano-sheets, nano-bars, nano-tubes, nano-wires, etc.) formed using the semiconductor layers 220. The semiconductor layers 230 are removed and replaced by metal-containing gate structures 720. For example, the metal-containing gate structures 720 may each include a high-k gate dielectric and a metal gate electrode. Another portion of the metal-containing gate structure 720 may be disposed over the side 431 of the stack of nano-structure channels.

Source/drain components 730 may also be formed on opposite sides of the gate structures 720 laterally. It is understood that the source/drain components 730 may refer to a source or a drain, individually or collectively, dependent upon the context. The source/drain components 730 may be formed by one or more epitaxial growth processes in some embodiments. Source/drain vias 750 may be formed from the side 430 of the IC device 300 to provide electrical connectivity to the source/drain components 730 from the side 430. Meanwhile, no electrical interconnections have been formed from the side 431 of the GAA transistors 700 at this stage fabrication yet. The dielectric structure 250, which may include a dielectric layer 250A (e.g., silicon oxide) and a dielectric layer 250B (e.g., silicon nitride), may be disposed over the GAA transistors 700 at this stage of fabrication shown in FIG. 10.

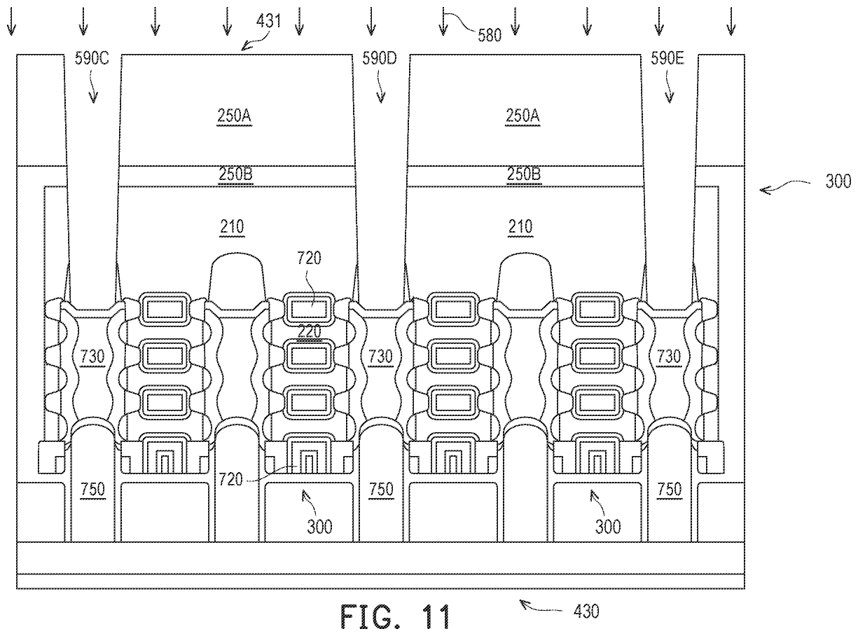

Referring now to FIG. 11, the one or more etching processes 580 discussed above with reference to FIG. 6 is also performed for this portion of the IC device 300. The one or more etching processes 580 also etch through the dielectric layers 250A and 250B, as well as a portion of the active region 210 to expose the source/drain components 730. As a result, via trench openings 590C, 590D, and 590E are formed. As discussed above, the via trench openings 590C, 590D, and 590E of FIG. 11 are formed at the same time (and using the same fabrication process/step) as the via trench openings 590A and 590B of FIG. 6.

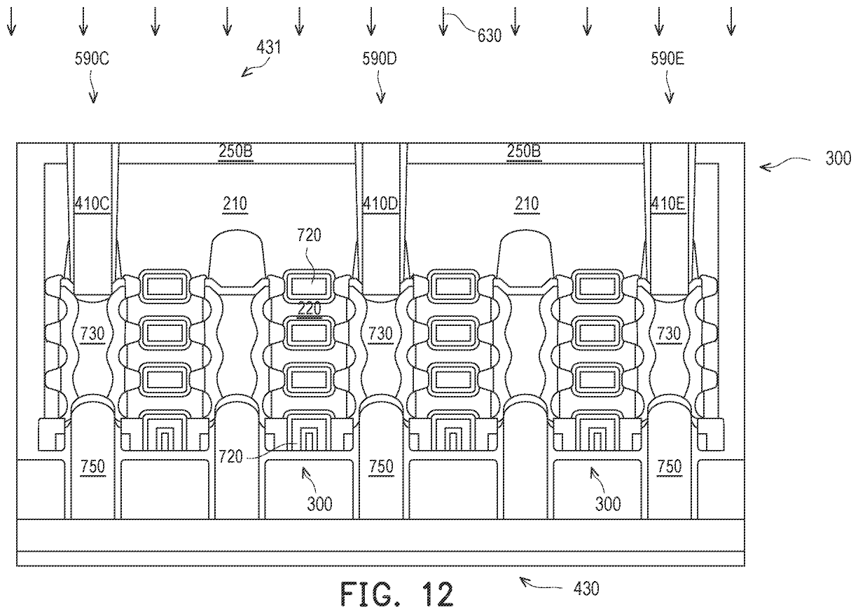

Referring now to FIG. 12, the deposition process 630 is performed to the IC device 300 to fill the via trench openings 590C-590E with a conductive material, thereby forming conductive vias 410C-410E. As discussed above, the conductive vias 610C, 610D, and 610E of FIG. 12 are formed at the same time (and using the same fabrication process/step) as the conductive vias 410A-410B of FIG. 8. The conductive vias 410C-410E are electrically coupled to the source/drain components 730 from the side 431 and provide electrical connectivity to the source/drain components 730 from the side 431 accordingly.

Based on the process flow of FIGS. 10-12 for the GAA transistors 700, it can be seen that the formation of the CPEC structure 400 of FIGS. 8-9 is fully compatible with the process flow for fabricating the GAA transistors 700. As such, fabrication costs and/or processing time can be reduced.

FIG. 13 illustrates an integrated circuit fabrication system 900 according to embodiments of the present disclosure, which may be used to fabricate the IC device 300 of the present disclosure. The fabrication system 900 includes a plurality of entities 902, 904, 906, 908, 910, 912, 914, 916 . . . , N that are connected by a communications network 918. The network 918 may be a single network or may be a variety of different networks, such as an intranet and the Internet, and may include both wire line and wireless communication channels.

In an embodiment, the entity 902 represents a service system for manufacturing collaboration; the entity 904 represents an user, such as product engineer monitoring the interested products; the entity 906 represents an engineer, such as a processing engineer to control process and the relevant recipes, or an equipment engineer to monitor or tune the conditions and setting of the processing tools; the entity 908 represents a metrology tool for IC testing and measurement; the entity 910 represents a semiconductor processing tool, such an EUV tool that is used to perform lithography processes; the entity 912 represents a virtual metrology module associated with the processing tool 910; the entity 914 represents an advanced processing control module associated with the processing tool 910 and additionally other processing tools; and the entity 916 represents a sampling module associated with the processing tool 910.

Each entity may interact with other entities and may provide integrated circuit fabrication, processing control, and/or calculating capability to and/or receive such capabilities from the other entities. Each entity may also include one or more computer systems for performing calculations and carrying out automations. For example, the advanced processing control module of the entity 914 may include a plurality of computer hardware having software instructions encoded therein. The computer hardware may include hard drives, flash drives, CD-ROMs, RAM memory, display devices (e.g., monitors), input/output device (e.g., mouse and keyboard). The software instructions may be written in any suitable programming language and may be designed to carry out specific tasks.

The integrated circuit fabrication system 900 enables interaction among the entities for the purpose of integrated circuit (IC) manufacturing, as well as the advanced processing control of the IC manufacturing. In an embodiment, the advanced processing control includes adjusting the processing conditions, settings, and/or recipes of one processing tool applicable to the relevant wafers according to the metrology results.

In another embodiment, the metrology results are measured from a subset of processed wafers according to an optimal sampling rate determined based on the process quality and/or product quality. In yet another embodiment, the metrology results are measured from chosen fields and points of the subset of processed wafers according to an optimal sampling field/point determined based on various characteristics of the process quality and/or product quality.

One of the capabilities provided by the IC fabrication system 900 may enable collaboration and information access in such areas as design, engineering, and processing, metrology, and advanced processing control. Another capability provided by the IC fabrication system 900 may integrate systems between facilities, such as between the metrology tool and the processing tool. Such integration enables facilities to coordinate their activities. For example, integrating the metrology tool and the processing tool may enable manufacturing information to be incorporated more efficiently into the fabrication process or the APC module, and may enable wafer data from the online or in site measurement with the metrology tool integrated in the associated processing tool.

FIG. 14 is a flowchart illustrating a method 1000 fabricating an IC device according to various aspects of the present disclosure. The method 1000 includes a step 1010 to form an active region that includes a plurality of interleaving first semiconductor layers and second semiconductor layers.

The method 1000 includes a step 1020 to dope a first portion of the active region with a P-type dopant.

The method 1000 includes a step 1030 to dope a second portion of the active region with an N-type dopant. The second portion of the active region is separated from the first portion of the active region by a third portion of the active region that is undoped.

The method 1000 includes a step 1040 to form a first interconnect structure over a first side of the first portion of the active region and the first side of the second portion of the active region, such that the first portion of the active region is electrically coupled to a first set of interconnection components of the first interconnect structure through the first side, and the second portion of the active region is electrically coupled to a second set of interconnection components of the first interconnect structure through the first side.

The method 1000 includes a step 1050 to form a second interconnect structure over a second side of the first portion of the active region and the second side of the second portion of the active region, such that the first portion of the active region is electrically coupled to a third set of interconnection components of the second interconnect structure through the second side, and the second portion of the active region is electrically coupled to a fourth set of interconnection components of the second interconnect structure through the second side. The first set of interconnection components is electrically coupled to the third set of interconnection components. The second set of interconnection components is electrically coupled to the fourth set of interconnection components.

In some embodiments, a dielectric structure is formed over the second side of the active region. In some embodiments, the forming the second interconnect structure comprises: etching, from the second side toward the first side, a first trench and a second trench through the dielectric structure, such that the first trench exposes a portion of the first portion of the active region from the second side, and that the second trench exposes a portion of the second portion of the active region from the second side; and filling the first trench and the second trench with a conductive material, thereby forming a first conductive via in the first trench and a second conductive via in the second trench.

In some embodiments, the dielectric structure includes a plurality of dielectric layers; the active region is formed on a semiconductor substrate; and the first trench and the second trench are etched to extend through the plurality of dielectric layers and at least partially through the semiconductor substrate.

In some embodiments, the forming the second interconnect structure further comprises forming a first metal line over the second side of the first conductive via and forming a second metal line over the second side of the second conductive via.

In some embodiments, the first metal line and the first conductive via are portions of the third set of interconnection components of the second interconnect structure; the second metal line and the second conductive via are portions of the fourth set of interconnection components of the second interconnect structure; the first set of interconnection components is electrically coupled to the first side of the first metal line; and the second set of interconnection components is electrically coupled to the first side of the second metal line.

In some embodiments, the first portion of the active region, the second portion of the active region, and the third portion of the active region collective form a PIN diode; the forming the second interconnect structure further comprises forming a first pad and a second pad over the second side of the first metal line and the second metal line, respectively; the first pad is configured to receive a first voltage for a P-terminal of the PIN diode; and the second pad is configured to receive a second voltage for an N-terminal of the PIN diode.

It is understood that additional processes may be performed before, during, or after the steps 1010-1050 of the method 1000. For example, in some embodiments, the method 1000 may further include a step of biasing the first set of interconnection components and the third set of interconnection components to a same first electrical voltage, and biasing the second set of interconnection components and the fourth set of interconnection components to a same second electrical voltage. As another example, the method 1000 may include a step of fabricating a gate-all-around (GAA) device at least in part using a fourth portion of the active region.

FIG. 15 is a flowchart illustrating a method 1000 fabricating an IC device according to various aspects of the present disclosure. The method 1000 includes a step 1010 to form a diode in an active region. The diode includes a P-type component embedded in a first portion of the active region, an N-type component embedded in a second portion of the active region, and an undoped component disposed between the P-type component and the N-type component.

The method 1000 includes a step 1020 to form an interconnect structure over a first side of the diode. Different portions of the interconnect structure are electrically coupled to the P-type component and the N-type component, respectively.

The method 1000 includes a step 1030 to etch one or more openings through a dielectric structure disposed over a second side of the diode opposite the first side.

The method 1000 includes a step 1040 to implant a dopant material into the active region through the one or more openings.

The method 1000 includes a step 1050 to fill the one or more openings with a conductive material.

In some embodiments, the active region includes a stack of first semiconductor layers and second semiconductor layers, the first semiconductor layers and the second semiconductor layers having different material compositions and interleaving with one another. In some embodiments, the forming the diode includes implanting a P-type dopant in a first portion of the active region and implanting an N-type dopant in a second portion of the active region, such that each of the P-type dopant and the N-type dopant penetrate through at least a subset of the stack of first semiconductor layers and second semiconductor layers.

In some embodiments, the implanting comprises implanting boron as the dopant material through the one or more openings.

In some embodiments, the implanting is performed such that the dopant material implanted into the active region does not reach the P-type component or the N-type component of the diode.

In some embodiments, the etching is performed such that each of the one or more openings is wider than the P-type component or the N-type component.

In some embodiments, the etching is performed such that none of the one or more openings expose the P-type component or the N-type component to the second side.

It is understood that additional processes may be performed before, during, or after the steps 1010-1050 of the method 1000. For example, in some embodiments, the diode is formed in a first portion of the active region, and the method 1100 further comprises a step of forming a gate-all-around (GAA) transistor at least in part in a second portion of the active region. The GAA transistor includes a source/drain component, and the etching is performed as a part of an etching process that etches a source/drain via opening for the source/drain component from the second side.

In summary, the present disclosure pertains to forming CPEC structures to reduce the potential harmful effects for diodes caused by positively charged plasma during fabrication. The present disclosure may offer advantages over conventional devices. However, it is understood that not all advantages are discussed herein, different embodiments may offer different advantages, and that no particular advantage is required for any embodiment. In that regard, various fabrication processes may involve using positively charged plasma, which can cause positively charged particles to enter a dielectric structure of the IC device containing the diode. The presence of the positively charged particles may then attract electrons at or near the surface of the dielectric structure, which could then adversely interfere with the performance and/or intended operation of the diode. One embodiment of the present disclosure addresses this issue by forming a CPEC structure that includes extra interconnection components, which may balance voltage potentials on both sides of the diode. As a result, it may be difficult for the positively charged particles to find a path to enter the dielectric structure. In turn, the harmful effects associated with the positively charged plasma may be lessened. Another embodiment of the present disclosure addresses this issue by forming extra P-type doped regions in the active region near the dielectric structure. The extra P-type doped regions are formed by leveraging the via formation processes that are also performed to form electrical interconnections for the regular transistors (e.g., GAA transistors) of the IC device, which includes a via trench formation process. After the via trenches are etched, but before they are filled, the P-type dopant material may be implanted through the open via trenches into the active region, which forms the P-type doped regions. The P-type doped regions attract and/or neutralize the electrons that would otherwise congregate near the dielectric structure. In this manner, the harmful effects associated with the positively charged plasma can also be reduced, and device performance can be improved. Other advantages may include compatibility with existing fabrication processes and the ease and low cost of implementation.

The advanced lithography process, method, and materials described above can be used in many applications, including in IC devices using fin-type field effect transistors (FinFETs). For example, the fins may be patterned to produce a relatively close spacing between features, for which the above disclosure is well suited. In addition, spacers used in forming fins of FinFETs, also referred to as mandrels, can be processed according to the above disclosure. It is also understood that the various aspects of the present disclosure discussed above may apply to multi-channel devices such as Gate-All-Around (GAA) devices. To the extent that the present disclosure refers to a fin structure or FinFET devices, such discussions may apply equally to the GAA devices.

One aspect of the present disclosure pertains to a device. The device includes a diode that includes a P-type region, an N-type region, and an undoped intrinsic region. A first conductive contact and a second conductive contact are each disposed over a first side of the diode. The first conductive contact is electrically coupled to the P-type region from the first side. The second conductive contact is electrically coupled to the N-type region from the first side. A first conductive via and a second conductive via are each disposed over a second side of the diode. The second side is different from the first side. The first conductive via is electrically coupled to the P-type region from the second side. The second conductive via is electrically coupled to the N-type region from the second side. The first conductive contact is electrically coupled to the first conductive via. The second conductive contact is electrically coupled to the second conductive via.

Another aspect of the present disclosure pertains to a device. The device includes an active region that includes a plurality of first semiconductor layers and a plurality of second semiconductor layers. The first semiconductor layers interleave with the second semiconductor layers. A PIN diode is formed in the active region. The PIN diode includes a P-type component, an N-type component, and an undoped component disposed between the P-type component and the N-type component. A first interconnect structure is formed over a first side of the PIN diode. The first interconnect structure includes a first set of interconnection components electrically coupled to the P-type component and a second set of interconnection components electrically coupled to the N-type component. A second interconnect structure is formed over a second side of the PIN diode. The second interconnect structure includes a third set of interconnection components electrically coupled to the P-type component and a fourth set of interconnection components electrically coupled to the N-type component. The first set of interconnection components and the third set of interconnection components have a same first voltage potential. The second set of interconnection components and the fourth set of interconnection components have a same second voltage potential.

Yet another aspect of the present disclosure pertains to a method. An active region is formed that includes a plurality of interleaving first semiconductor layers and second semiconductor layers. A first portion of the active region is doped with a P-type dopant. A second portion of the active region is doped with an N-type dopant. The second portion of the active region is separated from the first portion of the active region by a third portion of the active region that is undoped. A first interconnect structure is formed over a first side of the first portion of the active region and the first side of the second portion of the active region, such that the first portion of the active region is electrically coupled to a first set of interconnection components of the first interconnect structure through the first side, and the second portion of the active region is electrically coupled to a second set of interconnection components of the first interconnect structure through the first side. A second interconnect structure is formed over a second side of the first portion of the active region and the second side of the second portion of the active region, such that the first portion of the active region is electrically coupled to a third set of interconnection components of the second interconnect structure through the second side, and the second portion of the active region is electrically coupled to a fourth set of interconnection components of the second interconnect structure through the second side. The first set of interconnection components is electrically coupled to the third set of interconnection components. The second set of interconnection components is electrically coupled to the fourth set of interconnection components.

Another aspect of the present disclosure pertains to a device. The device includes a diode that includes a P-type region, an N-type region, and an undoped intrinsic region disposed between the P-type region and the N-type region. An interconnect structure is disposed over a first side of the diode. A plurality of conductive vias is disposed over a second side of the diode, the second side being different from the first side. One or more doped regions are disposed between the diode and the conductive vias.

Another aspect of the present disclosure pertains to a device. The device includes an active region that includes a plurality of interleaving first semiconductor layers and second semiconductor layers. A PIN diode is formed in the active region. The PIN diode includes a P-type component, an N-type component, and an undoped component disposed between the P-type component and the N-type component. A first conductive contact and a second conductive contact are disposed over a first side of the PIN diode. The first conductive contact and the second conductive contact are electrically coupled to the P-type component and the N-type component, respectively. A dielectric structure is disposed over a second side of the PIN diode opposite from the first side. One or more doped regions are disposed between the PIN diode and the dielectric structure, wherein the one or more doped regions each include a P-type dopant.

Yet one more aspect of the present disclosure pertains to a method. A diode is formed in an active region. The diode includes a P-type component embedded in a first portion of the active region, an N-type component embedded in a second portion of the active region, and an undoped component disposed between the P-type component and the N-type component. An interconnect structure is formed over a first side of the diode. Different portions of the interconnect structure are electrically coupled to the P-type component and the N-type component, respectively. One or more openings are etched through a dielectric structure disposed over a second side of the diode opposite the first side. A dopant material is implanted into the active region through the one or more openings. The one or more openings are filled with a conductive material.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A device, comprising:
a diode that includes a P-type region, an N-type region, and an undoped intrinsic region disposed between the P-type region and the N-type region;
an interconnect structure disposed over a first side of the diode;
a plurality of conductive vias disposed over a second side of the diode, the second side being different from the first side; and
one or more doped regions disposed between the diode and the conductive vias.

2. The device of claim 1, wherein the one or more doped regions are doped with a P-type dopant.

3. The device of claim 1, wherein one or more doped regions each have a wider lateral dimension than the P-type region or the N-type region in a cross-sectional side view.

4. The device of claim 1, further comprising a first isolation structure and a second isolation structure;
wherein:
the diode is disposed between the first isolation structure and the second isolation structure in a cross-sectional side view; and
the one or more doped regions span laterally from the first isolation structure to the second isolation structure.

5. The device of claim 1, wherein the one or more doped regions include a first doped region vertically aligned with the P-type region of the diode and a second doped region vertically aligned with the N-type region of the diode.

6. The device of claim 1, further comprising a dielectric layer disposed over the second side of the diode, wherein the conductive vias each extend vertically through the dielectric layer.

7. The device of claim 1, wherein the undoped intrinsic region includes a plurality of first semiconductor layers and a plurality of second semiconductor layers, the first semiconductor layers interleaving with the second semiconductor layers.

8. The device of claim 7, wherein:
the first semiconductor layers contain silicon; and
the second semiconductor layers contain silicon germanium.

9. The device of claim 7, wherein:
the P-type region includes a P-doped portion of the plurality of the first semiconductor layers and the second semiconductor layers; and
the N-type region includes an N-doped portion of the plurality of the first semiconductor layers and the second semiconductor layers.

10. The device of claim 1, wherein the diode is formed in a first region of the device, and wherein the device further comprises a second region in which a plurality of gate-all-around (GAA) transistors is formed.

11. A device, comprising:
an active region that includes a plurality of interleaving first semiconductor layers and second semiconductor layers;
a PIN diode formed in the active region, the PIN diode including a P-type component, an N-type component, and an undoped component disposed between the P-type component and the N-type component;
a first conductive contact and a second conductive contact disposed over a first side of the PIN diode, wherein the first conductive contact and the second conductive contact are electrically coupled to the P-type component and the N-type component, respectively;
a dielectric structure disposed over a second side of the PIN diode opposite from the first side; and
one or more doped regions disposed between the PIN diode and the dielectric structure, wherein the one or more doped regions each include a P-type dopant.

12. The device of claim 11, further comprising one or more conductive vias that each extend through the dielectric structure, wherein each of the one or more conductive vias is aligned with a respective one of the one or more doped regions.

13. The device of claim 11, wherein each doped region of the one or more doped regions is spaced apart from the P-type component and from the N-type component.

14. A method, comprising:
forming a diode in an active region, wherein the diode includes a P-type component embedded in a first portion of the active region, an N-type component embedded in a second portion of the active region, and an undoped component disposed between the P-type component and the N-type component;
forming an interconnect structure over a first side of the diode, wherein different portions of the interconnect structure are electrically coupled to the P-type component and the N-type component, respectively;
etching one or more openings through a dielectric structure disposed over a second side of the diode opposite the first side;
implanting a dopant material into the active region through the one or more openings; and
filling the one or more openings with a conductive material.

15. The method of claim 14, wherein:
the active region includes a stack of first semiconductor layers and second semiconductor layers, the first semiconductor layers and the second semiconductor layers having different material compositions and interleaving with one another; and
the forming the diode includes implanting a P-type dopant in a first portion of the active region and implanting an N-type dopant in a second portion of the active region, such that each of the P-type dopant and the N-type dopant penetrate through at least a subset of the stack of first semiconductor layers and second semiconductor layers.

16. The method of claim 14, wherein the implanting comprises implanting boron as the dopant material through the one or more openings.

17. The method of claim 14, wherein the implanting is performed such that the dopant material implanted into the active region does not reach the P-type component or the N-type component of the diode.

18. The method of claim 14, wherein the etching is performed such that each of the one or more openings is wider than the P-type component or the N-type component.

19. The method of claim 14, wherein the etching is performed such that none of the one or more openings expose the P-type component or the N-type component to the second side.

20. The method of claim 14, wherein the diode is formed in a first portion of the active region, wherein the method further comprises: forming a gate-all-around (GAA) transistor at least in part in a second portion of the active region;
wherein:
the GAA transistor includes a source/drain component; and
the etching is performed as a part of an etching process that etches a source/drain via opening for the source/drain component from the second side.
